(19) United States
(12) Patent Application Publication
(10) Pub. No.: US 2014/0326313 A1
(43) Pub. Date: Nov. 6, 2014

(54) Resin Composition for Encapsulating Film of Photovoltaic Module and Photovoltaic Module Using the Same

(71) Applicants: SK Innovation Co., Ltd., Seoul (KR); SK Global Chemical Co., Ltd., Seoul (KR)

(72) Inventors: Seung Gweon Hong, Daejeon (KR); Min Ho Jeon, Daejeon (KR); Kwang Jin Chung, Daejeon (KR); Ki Nam Chung, Daejeon (KR); Myung Ahn Ok, Daejeon (KR); In Hun Son, Daejeon (KR)

(73) Assignees: SK INNOVATION CO., LTD., Seoul (KR); SK GLOVAL CHEMICAL CO., LTD., Seoul (KR)

(21) Appl. No.: 14/352,408

(22) PCT Filed: Oct. 17, 2012
(86) PCT No.: PCT/KR2012/008449

§ 371 Date: Apr. 17, 2014

(30) Foreign Application Priority Data
Oct. 18, 2011 (KR) 10-2011-0106235

(51) Int. Cl. H01L 31/048; C08G 64/02

(52) U.S. Cl. CPC H01L 31/0481; C08G 64/0208
USPC 136/259; 528/405

(57) ABSTRACT

Provided are a resin composition for an encapsulating film of a photovoltaic module, and a photovoltaic module us ing the same, and more particularly, a resin composition for an encapsulating film of a photovoltaic module, having low moisture permeability and excellent adhesiveness due to thermal compression, and a photovoltaic module using the same, and thus, in the case where the resin composition for an encapsulating film of a photovoltaic module is used for a front sheet, a back sheet, or both of the front and back sheets, of a photovoltaic module, the resin composition can be used without an adhesive due to excellent transparency and durability against ultraviolet light and high adhesive strength with respect to glass, and thus can exhibit excellent compatibility.

### TECHNICAL FIELD

The present invention relates to a resin composition for an encapsulating film of a photovoltaic module and a photovoltaic module using the same, and more particularly to a resin composition for an encapsulating film of a photovoltaic module having low moisture permeability and excellent adhesiveness due to thermal compression and a photovoltaic module using the same.

### BACKGROUND ART

Solar energy is an energy source that is clean, reproducible, and infinite. A photovoltaic technology is a system technology that converts solar energy into electric energy. Since there are no mechanical and chemical actions in an energy conversion procedure thereof, a system therefor has a simple structure, and thus scarcely requires maintenance, has a long lifespan, and is safe and eco-friendly. In addition, the scale for electric generation may be verified from electric generation for home to large-scale electric generation.

A photovoltaic system is composed of a photovoltaic module receiving light to generate electricity, a battery storing the generated electricity, and a power conditioning system (PCS) serving functions of converting the electricity from direct current to alternating current and connecting this to a power system.

The photovoltaic module generally has a structure obtained by combining a plurality of solar cell devices, and forming encapsulating films on both surfaces of each of the solar cell devices through a filling adhesive resin to thereby receive and encapsulate the solar cell devices inside the encapsulating films (In general, an encapsulating film formed on a light incident side of a solar light (front surface) is referred to as a ┌front sheet┐, and an encapsulating film formed on a light non-incident side of a solar light (back surface) is referred to as a ┌back sheet┐).

In addition, the photovoltaic module is requested to have a long lifespan, without reduction of output power for 20 to 30 years.

For achieving a long lifespan thereof, it is important to block out moisture or oxygen that adversely affects the solar cell devices, or to prevent deterioration of an encapsulating film of a photovoltaic module (hereinafter, referred to as an encapsulating film) due to hydrolysis or ultraviolet light. In addition, the costs of the encapsulating film need to be reduced due to strong demand for lower price of the encapsulating film, and the encapsulating film needs to have a function of reflecting solar light.

In addition, studies on the improvement in conversion efficiency (conversion ratio of light into electricity) by making the encapsulating film highly transparent, to thereby increase the incident ratio of solar light.

The photovoltaic module of the related art has a structure where a solar cell is located between a safety glass layer, on which an EVA film is attached for enhancing safety of an upper layer portion and performing an encapsulating function, and an EVA back sheet for reflecting solar light and performing an encapsulating function. Herein, the back sheet performs a function of encapsulation directly associated with the lifespan of the solar cell and a function of again reflecting the light that passes through a solar cell layer for reducing the loss of solar light. Hence, the front sheet and back sheet of the photovoltaic module are requested to have strong adhesive strength with respect to a glass above, high adhesiveness by thermal compression, and low moisture permeability, but still do not meet these requirements.

### DISCLOSURE OF INVENTION

### Technical Problem

An object of the present invention is to provide a resin composition for an encapsulating film of a photovoltaic module having excellent adhesive strength with respect to a tempered glass layer of the photovoltaic module, and high light transmissibility to thereby have little loss of light, and a photovoltaic module using the same.

More specifically, an object of the present invention is to provide a resin composition for an encapsulating film of a photovoltaic module having excellent adhesive strength to thereby significantly improve an encapsulating function, by including a front sheet and a back sheet of the same material, and a photovoltaic module using the same.

### Solution to Problem

In order to achieve the above objects, there is provided a resin composition for an encapsulating film of a photovoltaic module including aliphatic polycarbonate.

Hereinafter, the present invention will be described in more detail.

Here, unless indicated otherwise, the terms used in the specification including technical and scientific terms have the same meaning as those that are usually understood by those who skilled in the art to which the present invention pertains, and detailed description of the known functions and constitutions that may obscure the gist of the present invention will be omitted.

The present invention is directed to a resin composition for an encapsulating film of a photovoltaic module and a photovoltaic module using the same. In one general aspect, the present invention provides a resin composition for an encapsulating film of a photovoltaic module including aliphatic polycarbonate obtained by reacting carbon dioxide with one epoxide compound or two or more different epoxide compounds selected from the group consisting of (C2-C10)alkylene oxide substituted or unsubstituted with halogen or alkoxy; (C4-C20)cycloalkylene oxide substituted or unsubstituted with halogen or alkoxy; and (C8-C20)styrene oxide substituted or unsubstituted with halogen, alkoxy, alkyl or aryl, and also provides a photovoltaic module using the same.

The alkoxy may be selected from alkyloxy, aryloxyl, aralkyloxy, and the like, but is not limited thereto. The aryloxy may be selected from phenoxy, biphenyloxy, naphthyloxy, and the like.

In addition, the alkoxy, alkyl, and aryl may be further substituted with a halogen atom or alkoxy.

More specifically, the aliphatic polycarbonate is characterized by being represented by Chemical Formula 1 below:

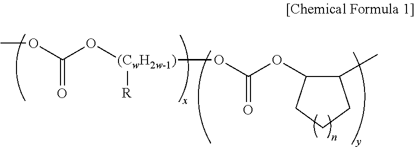

(wherein, w is an integer of 2 to 10; x is an integer of 5 to 100; y is an integer of 0 to 100; n is an integer of 1 to 3; and R is hydrogen, (C1-C4)alkyl, or —CH₂—O—R′(R′ is (C1˜C8)alkyl).

In the present invention, specific examples of the epoxide compound may include ethylene oxide, propylene oxide, butene oxide, pentene oxide, hexene oxide, octene oxide, decene oxide, dodecene oxide, tetradecene oxide, hexadecene oxide, octadecene oxide, butadiene monoxide, 1,2-epoxide-7-octene, epifluorohydrin, epichlorohydrin, epibromohydrin, isopropyl glycidyl ether, butyl glycidyl ether, t-butyl glycidyl ether, 2-ethylhexylglycidyl ether, allyl glycidyl ether, cyclopentene oxide, cyclohexene oxide, cyclooctene oxide, cyclododecene oxide, alpha-pinene oxide, 2,3-epoxide norbornene, limonene oxide, dieldrine, 2,3-epoxidepropylbenzene, styrene oxide, phenylpropylene oxide, stilbene oxide, chlorostilbene oxide, dichlorostilbene oxide, 1,2-epoxy-3-phenoxypropane, benzyloxymethyl oxirane, glycidyl-methylphenyl ether, chlorophenyl-2,3-epoxidepropyl ether, epoxypropyl methodyphenyl ether, biphenyl glycidyl ether, glycidyl naphthyl ether, and the like, but are not limited thereto.

The resin composition for an encapsulating film of a photovoltaic module is characterized by including aliphatic polycarbonate having a melting viscosity of 0.5˜9 Pa-sec at 180° C. The viscosity is proportional to the polymerization degree of an aliphatic polycarbonate polymer. If the viscosity of the resin composition is below 0.50 Pa-sec, it is difficult to impart hydrolysis resistance, light resistance, and heat resistance to the encapsulating film, resulting in deteriorating water resistance of the encapsulating film. On the contrary, if the intrinsic viscosity is above 10 Pa-sec, melted and extruded molding is difficult, resulting in deteriorating the film forming property and lowering adhesive strength.

The aliphatic polycarbonate of Chemical Formula 1 above may be prepared by solution polymerization or bulk polymerization, and more specifically, polymerization is performed by feeding carbon dioxide in the presence of one epoxide compound or two or more different epoxide compounds and a catalyst while an organic solvent is used as a reactive medium. As the organic solvent, aliphatic hydrocarbon, such as, pentane, octane, decane, cyclohexane, and the like; aromatic hydrocarbon, such as, benzene, toluene, xylene, and the like; and halogenated hydrocarbons, such as, chloromethane, methylene chloride, chloroform, carbontetrachloride, 1,1-dichloroethane, 1,2-dichloethane, ethylchloride, trichloroethane, 1-chloropropane, 2-chloropropane, 1-chlorobutane, 2-chlorobutane, 1-chloro-2-methylpropane, chlorobenzene, bromobenzene, and the like, may be used alone or in combination of two or more thereof. The pressure of carbon dioxide may be normal pressure to 100 atm, and preferably, 5 atm to 30 atm may be appropriate. The polymerization temperature at the time of copolymerization may be 20˜120° C., and preferably, 50˜90° C. may be appropriate. More preferably, bulk polymerization using a monomer itself as a solvent may be performed.

Hereinafter, a method for preparing the resin composition for an encapsulating film of a photovoltaic module according to the present invention will be described in more detail.

As the resin composition for an encapsulating film of a photovoltaic module according to the present invention, polypropylene carbonate having a melting viscosity of 0.5˜9 Pa-sec may be used. It is then extrusion-molded to be made into a film. Alternately, polyethylene carbonate or polypropylene carbonate random polymer may be used. To achieve this, at the time of copolymerizing carbon dioxide and alkylene oxide, propylene oxide and ethylene oxide, as the alkylene oxide, are mixed at a predetermined ratio, to thereby prepare a terpolymer. As the content of ethylene oxide becomes higher, the water barrier property is higher but the glass transition temperature is lower, resulting in lowering the strength of the film. Therefore, the content of ethylene oxide in the raw material is preferably 50 wt % or less.

In addition, the present invention is characterized by using a complex compound represented by Chemical Formula 2 below as a catalyst at the time of preparing aliphatic polycarbonate:

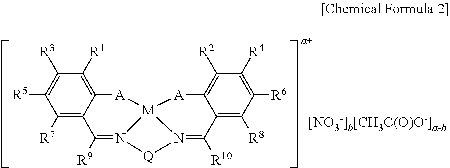

(wherein, M is trivalent cobalt or trivalent chromium; A is an oxygen or sulfur atom; Q is (C6˜C30)arylene, (C1˜C20)alkylene, (C2˜C20)alkenylene, (C2˜C20)alkynylene, or (C3˜C20)cycloalkylene; R¹ and R² each are independently primary (C1-C20)alkyl; R³ to R¹⁰ each are independently hydrogen; halogen; (C1-C20)alkyl; (C1-C20)alkyl containing at least one of halogen, nitrogen, oxygen, silicon, sulfur and phosphor; (C2-C20)alkenyl; (C2-C20)alkenyl containing at least one of halogen, nitrogen, oxygen, silicon, sulfur and phosphor; (C1-C20)alkyl(C6-C20)aryl; (C1-C20)alkyl(C6-C20)aryl containing at least one of halogen, nitrogen, oxygen, silicon, sulfur and phosphor; (C6-C20)aryl(C1-C20)alkyl; (C6-C20)aryl(C1-C20)alkyl containing at least one of halogen, nitrogen, oxygen, silicon, sulfur and phosphor; (C1-C20)alkoxy; (C6-C30)aryloxy; formyl; (C1-C20)alkylcarbonyl; (C6-C20)arylcarbonyl; or a metalloid radical of Group 14 metal substituted with hydrocarbyl; two of R¹ to R¹⁰ may be linked to each other to form a ring; at least three of R³ to R¹⁰ are protonated groups selected from the group consisting of compounds of Chemical Formulas a, b, and c;

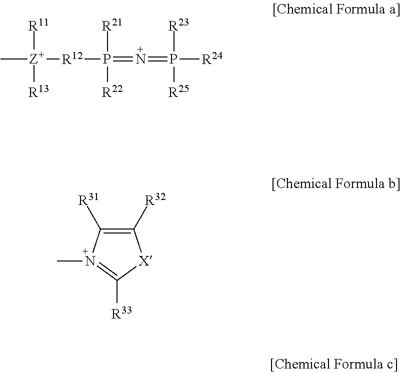

Z is nitrogen or phosphorus; R¹¹, R¹², R¹³, R²¹, R²², R²³, R²⁴ and R²⁵ each are independently (C1-C20)alkyl; (C1-C20)alkyl containing at least one of halogen, nitrogen, oxygen, silicon, sulfur and phosphor; (C2-C20)alkenyl; (C2-C20)alkenyl containing at least one of halogen, nitrogen, oxygen, silicon, sulfur and phosphor; (C1-C20)alkyl(C6-C20)aryl; (C1-C20)alkyl(C6-C20)aryl containing at least one of halogen, nitrogen, oxygen, silicon, sulfur and phosphor; (C6-C20)aryl(C1-C20)alkyl; (C6-C20)aryl(C1-C20)alkyl containing at least one of halogen, nitrogen, oxygen, silicon, sulfur and phosphor; or a metalloid radical of Group 14 metal substituted with hydrocarbyl; two of R¹¹, R¹² and R¹³ or two of R²¹, R²², R²³, R²⁴, and R²⁵ may be linked to each other to form a ring; R³¹, R³², and R³³ each are independently (C1-C20)alkyl; (C1-C20)alkyl containing at least one of halogen, nitrogen, oxygen, silicon, sulfur and phosphor; (C2-C20)alkenyl; (C2-C20)alkenyl containing at least one of halogen, nitrogen, oxygen, silicon, sulfur and phosphor; (C1-C20)alkyl(C6-C20)aryl; (C1-C20)alkyl(C6-C20)aryl containing at least one of halogen, nitrogen, oxygen, silicon, sulfur and phosphor; (C6-C20) aryl(C1-C20) alkyl; (C6-C20)aryl(C1-C20)alkyl containing at least one of halogen, nitrogen, oxygen, silicon, sulfur and phosphor; or a metalloid radical of Group 14 metal substituted with hydrocarbyl; two of R³¹, R³², and R³³ may be linked to each other to form a ring; X′ is oxygen, sulfur, or N—R (here, R is (C1-C20)alkyl); a is the number of protonated groups contained in R³ to R¹⁰ plus+1; b is an integer of 1 or greater; and nitrate or acetate negative ions may be coordinated to M).

Further, in the complex compound represented by Chemical Formula 2 above, M is trivalent cobalt; A is oxygen; Q is trans-1,2-cyclohexylene, phenylene, or ethylene; R¹ and R² each are independently methyl or ethyl; R³ to R¹⁰ each are independently hydrogen or —[YR⁴¹₃₋ₘ{(CR⁴²R⁴³)ₙN⁺R⁴⁴R⁴⁵R⁴⁶}ₘ], Y is C or Si; R⁴¹, R⁴², R⁴³, R⁴⁴, R⁴⁵ and R⁴⁶ each are independently hydrogen, (C1-C20)alkyl; (C1-C20)alkyl containing at least one of halogen, nitrogen, oxygen, silicon, sulfur and phosphor; (C2-C20)alkenyl; (C2-C20)alkenyl containing at least one of halogen, nitrogen, oxygen, silicon, sulfur and phosphor; (C1-C20)alkyl(C6-C20)aryl; (C1-C20)alkyl(C6-C20)aryl containing at least one of halogen, nitrogen, oxygen, silicon, sulfur and phosphor; (C6-C20)aryl(C1-C20)alkyl; (C6-C20)aryl(C1-C20)alkyl containing at least one of halogen, nitrogen, oxygen, silicon, sulfur and phosphor; or a metalloid radical of Group 14 metal substituted with hydrocarbyl; two of R⁴⁴, R⁴⁵ and R⁴⁶ may be linked to each other to form a ring; m is an integer of 1 to 3; and n is an integer of 1 to 20; provided that, at least three of R³ to R¹⁰ are —[YR⁴¹₃₋ₘ{(CR⁴²R⁴³)ⁿN⁺R⁴⁴R⁴⁵R⁴⁶}ₘ] when m is 1, at least two of R³ to R¹⁰ are —[YR⁴¹₃₋ₘ{(CR⁴²R⁴³)ₙN₊R⁴⁴R⁴⁵R⁴⁶}ₘ] when m is 2, and at least one of R³ to R¹⁰ are —[YR⁴¹₃₋ₘ{(CR⁴²R⁴³)ₙN⁺R⁴⁴R⁴⁵R⁴⁶}ₘ] when m is 3).

The present invention provides an encapsulating film of a photovoltaic module using the resin composition for an encapsulating film of the photovoltaic module.

The encapsulating film is characterized by being a front sheet or a back sheet, and the photovoltaic module is referred to one where a reinforced glass, a front sheet attached underneath the reinforced glass, a solar cell attached underneath the front sheet, and a back sheet attached underneath the solar cell are laminated.

The front sheet, back sheet, or front and back sheets made of the resin composition for an encapsulating film of a photovoltaic module according to the present invention can be used without an adhesive due to high adhesive strength thereof with respect to glass; can have excellent wettability of a film surface in the case where an adhesive is used due to the need of stronger adhesive strength; and have excellent compatibility with various adhesives due to high polarity, as well as have excellent transparency and durability with respect to ultraviolet rays.

These enhanced transparency and adhesive strength, even though the film is thickened, can reduce the loss of transmitted light, thereby improving safety of the glass, and allow the use of the sheet without an adhesive, thereby simplifying the lamination process.

In addition, the front sheet, the back sheet, or the front sheet and the back sheet may further include a titanium dioxide dye coated with organic silane to thereby lower reactivity with ultraviolet light or visible light. There can be provided a photovoltaic module having an improved encapsulating effect, by further including the dye to thereby further enhance adhesive strength with glass and improve adhesive property in addition to basic physical properties such as weather resistance, light reflectance, and the like.

The front sheet is characterized by having moisture permeability of 65 g/m2-day or less and gas permeability of 5 cc/100 in2-24 h-atm-mil or less. The back sheet is characterized by having equal moisture and gas blocking properties and a visible light reflectance of 97% or more.

### Advantageous Effects of Invention

As set forth above, the resin composition for an encapsulating film of a photovoltaic module according to the present invention is applied to the front sheet, the back sheet, or the front sheet and the back sheet, so that, the sheets can have excellent transparency and durability against ultraviolet light, and high adhesive strength with respect to glass whereby the sheets can be used without an adhesive. Further, the sheets can have excellent wettability of a film surface in the case where an adhesive is used due to the need of stronger adhesive strength, and have excellent compatibility with various adhesives due to high polarity.

Further, the front sheet, the back sheet, or both the front and back sheets can have enhanced adhesive strength with respect to glass and improved physical properties such as weather resistance, light reflectance, and the like, by further including titanium dioxide coated with organic silane.

### BEST MODE FOR CARRYING OUT THE INVENTION

Hereinafter, the present invention will be understood and appreciated more fully from the following examples, and the examples are for illustrating the present invention and not for limiting the present invention.

### Experimental Example

A polypropylene carbonate sheet (50 μm) was formed by using an extruder. Moisture permeability thereof was measured according to ISO 15106, and peel strength was measured according to GB/T2790. Tensile strength was measured according to GB/T1040.

### Preparative Example 1

### Synthesis of 3-methyl-5-[{BF₄⁻Bu₃N⁺(CH₂)₃}₂CH}]⁻ salicylaldehyde

The ligand having a structure below was hydrolyzed to prepare a target compound. The compound was synthesized according to the known method (Angew. Chem. Int. Ed., 2008, 47, 7306-7309).

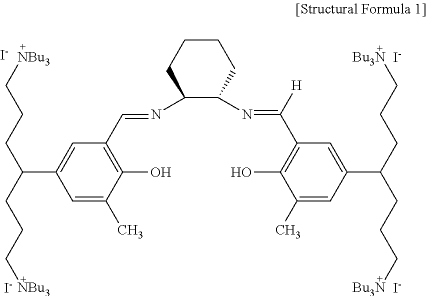

The compound of Structural Formula 1 (0.500 g, 0.279 mmol) was dissolved in methylene chloride (4 mL), and then an aqueous HI solution (2 N, 2.5 mL) was put thereinto, following by stirring at 70° C. for 3 hours. The water layer was removed, and the methylene chloride layer was washed with water. Then, moisture was removed by anhydrous magnesium chloride, and the solvent was removed under reduced pressure. Purification was performed by silica gel column chromatography using a mixture solution of methylene chloride/ethanol (10:1), to thereby obtain 0.462 g of 3-methyl-5-[{I-Bu₃N⁺(CH₂)₃}₂CH}]-salicylaldehyde (yield, 95%). This compound was dissolved in ethanol (6 mL), and AgBF4 (0.225 g, 1.16 mmol) was added thereto, followed by stirring at room temperature for 1.5 hours and then filtering. The solvent was removed under reduced pressure, and then, purification was performed by silica gel column chromatography using a mixture solution of methylene chloride/ethanol (10:1), to thereby obtain 0.410 g of 3-methyl-5-[{BF₄⁻Bu₃N⁺(CH₂)₃}₂CH}]-salicylaldehyde (100%).

¹H NMR (CDCl₃): δ 11.19 (s, 1H, OH), 9.89 (s, 1H, CHO), 7.48 (s, 1H, m-H), 7.29 (s, 1H, m-H), 3.32-3.26 (m, 4H, —NCH₂), 3.10-3.06 (m, 12H, —NCH₂), 2.77 (septet, J=6.8 Hz, 1H, —CH—), 2.24 (s, 3H, —CH₃), 1.76-1.64 (m, 8H, —CH₂), 1.58-1.44 (m, 16H, —CH₂), 1.34-1.29 (m, 8H, —CH₂), 0.90 (t, J=7.6 Hz, 18H, CH₃) ppm. 13C {¹H} NMR (CDCl₃): δ 197.29, 158.40, 136.63, 133.48, 130.51, 127.12, 119.74, 58.23, 40.91, 32.51, 23.58, 19.48, 18.82, 15.10, 13.45 ppm.

### Preparative Example 2

### Synthesis of Complex Compound 1

Complex compound 1 of Chemical Formula 13 below was synthesized from the 3-methyl-5-[{BF₄⁻Bu₃N⁺(CH₂)₃}₂CH}]-salicylaldehyde obtained in Preparative Example 1.

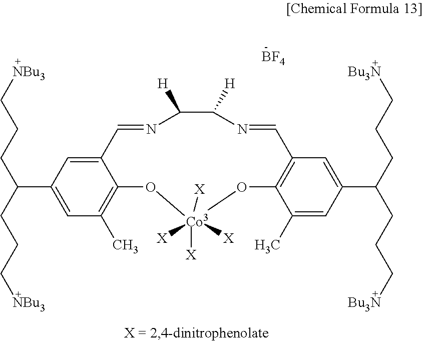

Ethylenediamine dihydrochloride (10 mg, 0.074 mmol), sodium t-butoxide (14 mg), and 3-methyl-5-[{BF₄⁻Bu₃N⁺(CH₂)₃}₂CH}]-salicylaldehyde compound (115 mg) prepared in Preparative Example 1 were weighed and put into a vial inside a dry box, and then ethanol (2 mL) was put thereinto, followed by stirring at room temperature overnight. The reaction mixture was filtered. The filtrate was taken, and then ethanol was removed under reduced pressure. Methylene chloride was again dissolved therein, and then filtering was performed one more time. The solvent was removed under reduced pressure, and then Co(OAc)₂ (13 mg, 0.074 mmol) and ethanol (2 mL) were added thereto. The reaction mixture was stirred at room temperature for 3 hours, and then the solvent was removed under reduced pressure. The thus obtained compound was washed with diethylether (2 mL) two times, to thereby obtain a solid compound. This solid compound was again dissolved in methylene chloride (2 mL), and 2,4-dinitrophenol (14 mg, 0.074 mmol) was added thereto, followed by stirring for 3 hours in the presence of oxygen. Sodium 2,4-dinitrophenolate (92 mg, 0.44 mmol) was added to the reaction mixture, followed by stirring overnight. Filtering using cellite was performed, and the solvent was removed, to thereby obtain a dark-brown solid compound (149 mg, 100%).

¹H NMR (dmso-d6, 40° C.): δ 8.84 (br, 2H, (NO₂)₂C₆H₃O), 8.09 (br, 2H, (NO₂)₂C₆H₃O), 8.04 (s, 1H, CH═N), 7.12 (s, 2H, m-H), 6.66 (br, 2H, (NO₂)₂C₆H₃O), 4.21 (br, 2H, ethylene-CH₂), 3.35-2.90 (br, 16H, NCH₂), 2.62 (s, 3H, CH₃), 1.91 (s, 1H, CH), 1.68-1.42 (br, 20H, CH₂), 1.19 (br, 12H, CH₂), 0.83 (br, 18H, CH₃) ppm. ¹H NMR (THF-d8, 20° C.): δ 8.59 (br, 1H, (NO₂)₂C₆H₃O), 8.10 (br, 1H, (NO₂)₂C₆H₃O), 7.93 (s, 1H, CH═N), 7.88 (br, 1H, (NO₂)₂C₆H₃O), 7.05 (s, 1H, m-H), 6.90 (s, 1H, m-H), 4.51 (s, 2H, ethylene-CH₂), 3.20-2.90 (br, 16H, NCH₂), 2.69 (s, 3H, CH₃), 1.73 (s, 1H, CH), 1.68-1.38 (br, 20H, CH₂), 1.21 (m, 12H, CH₂), 0.84 (t, J=6.8 Hz, 18H, CH₃) ppm. 1H NMR (CD₂Cl₂, 20° C.): δ 8.43 (br, 1H, (NO₂)₂C₆H₃O), 8.15 (br, 1H, (NO₂)₂C₆H₃O), 7.92 (br, 1H, (NO₂)₂C₆H₃O), 7.79 (s, 1H, CH═N), 6.87 (s, 1H, m-H), 6.86 (s, 1H, m-H), 4.45 (s, 2H, ethylene-CH₂), 3.26 (br, 2H, NCH₂), 3.0-2.86 (br, 14H, NCH₂), 2.65 (s, 3H, CH₃), 2.49 (br, 1H, CH), 1.61-1.32 (br, 20H, CH₂), 1.31-1.18 (m, 12H, CH₂), 0.86 (t, J=6.8 Hz, 18H, CH₃) ppm. 13C{1H} NMR (dmso-d6, 40° C.): δ 170.33, 165.12, 160.61, 132.12 (br), 129.70, 128.97, 127.68 (br), 124.51 (br), 116.18 (br), 56.46, 40.85, 31.76, 21.92, 18.04, 16.16, 12.22 ppm. ¹⁵N{¹H} NMR (dmso-d₆, 20° C.): δ −156.32, −159.21 ppm. ¹⁵N{¹H} NMR (THF-d₈, 20° C.): δ −154.19 ppm. ¹⁹F{¹H} NMR (dmso-d₆, 20° C.): δ −50.63, −50.69 ppm.

### Preparative Example 3

### Synthesis of Copolymer (PPC) Using Carbon Dioxide/Propylene Oxide

Propylene oxide (1162 g, 20.0 mol) having the complex compound (0.454 g, which is an amount calculated according to the monomer/catalyst ratio) dissolved therein was injected to a 3 L autoclave reactor through a cannula. Complex compound 1 prepared according to Preparative Example 2 was used as the complex compound. Carbon dioxide was put into the reactor at a pressure of 17 bar, and the resulting mixture was stirred within a circulation water bath, of which the temperature was previously set to 70° C., while increasing the temperature of the reactor. After 30 minutes, the time point when a pressure of the carbon dioxide starts to fall was recorded. The reaction was advanced for 2 hours from the time point, and then carbon dioxide was degassed to thereby finish the reaction. 830 g of propylene oxide was further added into the thus obtained viscous solution to thereby lower viscosity of the solution. Then the resulting solution was passed through silica gel (50 g, Merck Company, 0.040˜0.063 mm particle size (230˜400 mesh)), thereby obtaining a colorless solution. The resulting solution was subjected to vacuum decompressing to remove monomers, thereby obtaining 283 g of white solid. The thus obtained polymer had a weight average molecular weight (Mw) of 290,000 and a polydispersity index (PDI) of 1.30. The weight average molecular weight and polydispersity index of the thus obtained polymer were measured by using GPC.

### Preparative Example 4

### Synthesis of Terpolymer (CO2/PO/CHO Terpolymer) Using Carbon Dioxide/Propylene Oxide/Cyclohexene Oxide

Propylene oxide (622.5 g, 10.72 mol) having the complex compound (0.406 g, which is an amount calculated according to the monomer/catalyst ratio) dissolved therein was injected to a 3 L autoclave reactor through a cannula. Complex compound 1 prepared according to Preparative Example 2 was used as the complex compound. Carbon dioxide was put into the reactor at a pressure of 17 bar, and the resulting mixture was stirred within a circulation water bath, of which the temperature was previously set to 80° C., while increasing the temperature of the reactor. After 30 minutes, the time point when a pressure of the carbon dioxide starts to fall was recorded. From the time point, the reaction was advanced for 2 hours, and then carbon dioxide was degassed to thereby finish the reaction. 830 g of propylene oxide was further added into the thus obtained viscous solution to thereby lower viscosity of the solution. Then the resulting solution was passed through silica gel (50 g, Merck Company, 0.040˜0.063 mm particle size (230˜400 mesh)), thereby obtaining a colorless solution. The resulting solution was subjected to vacuum decompressing to thereby remove monomers, thereby obtaining 283 g of white solid.

The thus obtained polymer had a weight average molecular weight (Mw) of 210,000 and a polydispersity index (PDI) of 1.26, and the ratio of cyclohexene carbonate in the polymer was 25 mol %. The weight average molecular weight and polydispersity index of the thus obtained polymer were measured by using GPC, and the ratio of cyclohexene carbonate in the polymer was calculated by analyzing 1H NMR spectrum.

### Example 1

A PPC pellet, 0.3 phr of a UV absorbent, and 0.5 phr of an antioxidant were blended and then extruded, and then a rutile structure of titanium dioxide was again blended therewith and then extruded, to thereby manufacture a back sheet. Physical properties of the sheet were measured. The sheet was heat-attached to a glass, and then the following experiments were carried out.

### Example 2

0.3 phr of a UV absorbent and 0.5 phr of an antioxidant were blended with a poly(propylene-cyclohexene carbonate terpolymer (PPCC) pellet, followed by extrusion, and then a rutile structure of titanium dioxide was again blended therewith and then extruded by using a twin extruder, to thereby manufacture a back sheet. Physical properties of the sheet were measured. The sheet was heat-attached to a glass, and then items listed in Table 1 were evaluated.

### Comparative example 1

0.3 phr of a UV absorbent and 0.5 phr of an antioxidant were blended with ethylene vinyl acetate (EVA) having a vinylacetate content of 30%, followed by extrusion, and then a rutile structure of titanium dioxide was again blended therewith and then extruded, to thereby manufacture a back sheet. The back sheet was heat-attached to a glass, and then items of Table 1 below were evaluated.

TABLE 1

| | | | Comparative |
|---|---|---|---|
| | Example 1 | Example 2 | Example 1 |
| | PPC back | PPCC back | EVA back |
| | sheet | sheet | sheet |
| Reflectance (%) | 99 | 99 | 99 |
| Adhesive strength | Not | Not | Adhesive |
| | separated | separated | needs to be |
| | without | without | used, and |
| | adhesive | adhesive | separation |
| Moisture permeability | <60 | <50 | <52 |
| (20° C., 24 h), g/m²-day | | | |
| Peeling Strength | >39 | >37 | >36 |
| (N/cm) for glass | | | |
| UV ageing (delta YI) | 0 | 0.02 | 0.05 |

It can be seen from Table 1 above, that the photovoltaic module using the resin composition for an encapsulating film of a photovoltaic module, containing aliphatic polycarbonate, according to the present invention, had superior light transmittance and equal level of adhesive strength, as compared with that using the existing EVA.

1. A resin composition for an encapsulating film of a photovoltaic module, the resin composition comprising, aliphatic polycarbonate obtained by reacting carbon dioxide with one epoxide compound or two or more different epoxide compounds selected from the group consisting of (C2-C10)alkylene oxide substituted or unsubstituted with halogen or alkoxy; (C4-C20)cycloalkylene oxide substitute or unsubstituted with halogen or alkoxy; and (C8-C20)styrene oxide substituted or unsubstituted with halogen, alkoxy, alkyl or aryl.

2. The resin composition of claim 1, wherein the aliphatic polycarbonate is represented by Chemical Formula 1 below: 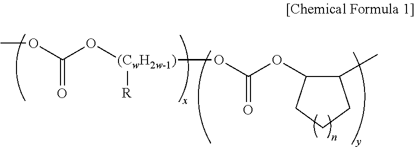
(in Chemical Formula 1, w is an integer of 2 to 10; x is an integer of 5 to 100; y is an integer of 0 to 100; n is an integer of 1 to 3; and R is hydrogen, (C1-C4)alkyl, or —CH₂—O—R′(R′ is (C1˜C8)alkyl).

3. The resin composition of claim 1, wherein it has a melting viscosity of 0.5˜9 Pa-sec at 180° C.

4. The resin composition of claim 1, wherein the aliphatic polycarbonate is prepared by using, as a catalyst, a compound represented by Chemical Formula 2 below: 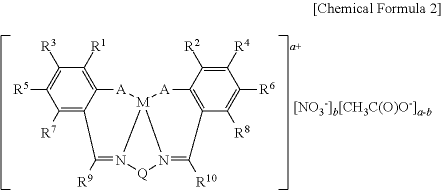
(in Chemical Formula 2,
M is trivalent cobalt or trivalent chromium;
A is an oxygen or sulfur atom;
Q is (C6˜C30)arylene, (C1˜C20)alkylene, (C2˜C20)alkenylene, (C2˜C20)alkynylene, or (C3˜C20)cycloalkylene;
R¹ and R² each are independently primary (C1-C20)alkyl;
R³ to R¹⁰ each are independently hydrogen; halogen; (C1-C20)alkyl; (C1-C20)alkyl containing at least one of halogen, nitrogen, oxygen, silicon, sulfur and phosphor; (C2-C20)alkenyl; (C2-C20)alkenyl containing at least one of halogen, nitrogen, oxygen, silicon, sulfur and phosphor; (C1-C20)alkyl(C6-C20)aryl; (C1-C20)alkyl(C6-C20)aryl containing at least one of halogen, nitrogen, oxygen, silicon, sulfur and phosphor; (C6-C20)aryl(C1-C20)alkyl; (C6-C20)aryl(C1-C20)alkyl containing at least one of halogen, nitrogen, oxygen, silicon, sulfur and phosphor; (C1-C20)alkoxy; (C6-C30)aryloxy; formyl; (C1-C20)alkylcarbonyl; (C6-C20)arylcarbonyl; or a metalloid radical of Group 14 metal substituted with hydrocarbyl;
two of R¹ to R¹⁰ may be linked to each other to form a ring;
at least three of R³ to R¹⁰ are protonated groups selected from the group consisting of compounds of Chemical Formulas a, b, and c; 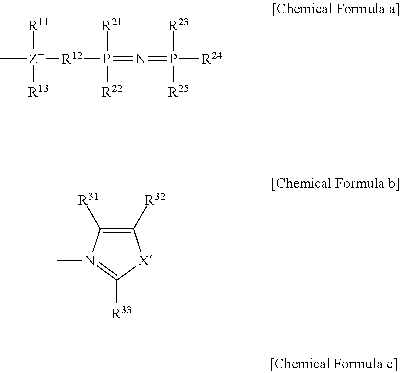
Z is nitrogen or phosphorus;
R¹¹, R¹², R¹³, R²¹, R²², R²³, R²⁴ and R²⁵ each are independently (C1-C20)alkyl; (C1-C20)alkyl containing at least one of halogen, nitrogen, oxygen, silicon, sulfur and phosphor; (C2-C20)alkenyl; (C2-C20)alkenyl containing at least one of halogen, nitrogen, oxygen, silicon, sulfur and phosphor; (C1-C20)alkyl(C6-C20)aryl; (C1-C20)alkyl(C6-C20)aryl containing at least one of halogen, nitrogen, oxygen, silicon, sulfur and phosphor; (C6-C20)aryl(C1-C20)alkyl; (C6-C20)aryl(C1-C20)alkyl containing at least one of halogen, nitrogen, oxygen, silicon, sulfur and phosphor; or a metalloid radical of Group 14 metal substituted with hydrocarbyl;
two of R¹¹, R¹² and R¹³ or two of R²¹, R²², R²³, R²⁴, and R²⁵ may be linked to each other to form a ring;
R³¹, R³², and R³³ each are independently (C1-C20)alkyl; (C1-C20)alkyl containing at least one of halogen, nitrogen, oxygen, silicon, sulfur and phosphor; (C2-C20)alkenyl; (C2-C20)alkenyl containing at least one of halogen, nitrogen, oxygen, silicon, sulfur and phosphor; (C1-C20)alkyl(C6-C20)aryl; (C1-C20)alkyl(C6-C20)aryl containing at least one of halogen, nitrogen, oxygen, silicon, sulfur and phosphor; (C6-C20)aryl(C1-C20)alkyl; (C6-C20)aryl(C1-C20)alkyl containing at least one of halogen, nitrogen, oxygen, silicon, sulfur and phosphor; or a metalloid radical of Group 14 metal substituted with hydrocarbyl;
two of R³¹, R³², and R³³ may be linked to each other to form a ring;
X′ is oxygen, sulfur, or N—R (here, R is (C1-C20)alkyl);
a is the number of protonated groups contained in R³ to R¹⁰ plus+1;
b is an integer of 1 or greater; and
nitrate or acetate negative ions may be coordinated to M).

5. The resin composition of claim 4, wherein in the complex compound represented by Chemical Formula 2 above,
M is trivalent cobalt;
A is oxygen;
Q is trans-1,2-cyclohexylene, phenylene, or ethylene;
R¹ and R² each are independently methyl or ethyl;
R³ to R¹⁰ each are independently hydrogen or —[YR⁴¹₃₋ₘ{(CR⁴²R⁴³)ₙN⁺R⁴⁴R⁴⁵R⁴⁶}ₘ];
Y is C or Si;
R⁴¹, R⁴², R⁴³, R⁴⁴, R⁴⁵ and R⁴⁶ each are independently (C1-C20)alkyl; (C1-C20)alkyl containing at least one of halogen, nitrogen, oxygen, silicon, sulfur and phosphor; (C2-C20)alkenyl; (C2-C20)alkenyl containing at least one of halogen, nitrogen, oxygen, silicon, sulfur and phosphor; (C1-C20)alkyl(C6-C20)aryl; (C1-C20)alkyl(C6-C20)aryl containing at least one of halogen, nitrogen, oxygen, silicon, sulfur and phosphor; (C6-C20)aryl(C1-C20)alkyl; (C6-C20)aryl(C1-C20)alkyl containing at least one of halogen, nitrogen, oxygen, silicon, sulfur and phosphor; or a metalloid radical of Group 14 metal substituted with hydrocarbyl;
two of R⁴⁴, R⁴⁵ and R⁴⁶ may be linked to each other to form a ring;
m is an integer of 1 to 3; and
n is an integer of 1 to 20;
provided that, at least three of R³ to R¹⁰ are —[YR⁴¹₃₋ₘ{(CR⁴²R⁴³)ₙN⁺R⁴⁴R⁴⁵R⁴⁶}ₐ] when m is 1, at least two of R³ to R¹⁰ are —[YR⁴¹₃₋ₘ{(CR⁴²R⁴³)ₙN⁺R⁴⁴R⁴⁵R⁴⁶}ₐ] when m is 2, and at least one of R³ to R¹⁰ are —[YR⁴¹₃₋ₘ{(CR⁴²R⁴³)ₙN⁺R⁴⁴R⁴⁵R⁴⁶}ₐ] when m is 3).

6. An encapsulating film of a photovoltaic module, the encapsulating film using the resin composition for an encapsulating film of a photovoltaic module of claim 1.

7. The encapsulating film of claim 6, wherein it is a front sheet or a back sheet.

8. The encapsulating film of claim 7, wherein the front sheet, the back sheet, or both of the front and back sheets further include titanium dioxide coated with organic silane.
